(19) United States
(12) Patent Application Publication
(10) Pub. No.: US 2023/0155027 A1
(43) Pub. Date: May 18, 2023

(54) ELECTRONIC DEVICE

(71) Applicant: InnoCare Optoelectronics Corporation, Tainan City (TW)

(72) Inventors: Zhi-Hong Wang, Tainan City (TW); Hsin-Hung Lin, Tainan City (TW)

(73) Assignee: InnoCare Optoelectronics Corporation, Tainan City (TW)

(21) Appl. No.: 17/973,563

(22) Filed: Oct. 26, 2022

Related U.S. Application Data
(60) Provisional application No. 63/279,182, filed on Nov. 15, 2021.

(30) Foreign Application Priority Data
Aug. 17, 2022 (CN) 202210989369.4

(51) Int. Cl. H01L 29/786; H01L 29/417; H01L 27/144

(52) U.S. Cl. CPC H01L 29/78606; H01L 29/78696; H01L 29/41733; H01L 27/1443

(57) ABSTRACT

The disclosure provides an electronic device. The electronic device includes a substrate, a transistor, and a first insulating layer. The transistor is disposed on the substrate and includes a source electrode, a drain electrode, and a gate electrode. The first insulating layer is disposed between the source electrode and the gate electrode and between the drain electrode and the gate electrode. The first insulating layer has a first portion and a second portion. The first portion is defined as a portion overlapped with the source electrode and the drain electrode. The second portion is defined as a portion not overlapped with the source electrode and the drain electrode. A thickness of the first portion is greater than a thickness of the second portion. The electronic device of an embodiment of the disclosure may reduce transistor characteristic shift or improve transistor performance.

### CROSS-REFERENCE TO RELATED APPLICATION

This application claims the priority benefit of U.S. provisional application Ser. No. 63/279,182, filed on Nov. 15, 2021, and China application serial no. 202210989369.4, filed on Aug. 17, 2022. The entirety of each of the above-mentioned patent applications is hereby incorporated by reference herein and made a part of this specification.

### BACKGROUND

### Technical Field

The disclosure relates to an electronic device, and more particularly, to an electronic device that may reduce transistor characteristic shift or improve transistor performance.

### Description of Related Art

Electronic devices or tiled electronic devices have been widely used in different fields such as communication, display, passenger transportation, and medical treatment. With the vigorous development of electronic devices, there are higher requirements for the reliability or quality of electronic devices.

### SUMMARY

The disclosure is directed to an electronic device that may reduce transistor characteristic shift or improve transistor performance.

According to an embodiment of the disclosure, an electronic device includes a substrate, a transistor, and a first insulating layer. The transistor is disposed on the substrate and includes a source electrode, a drain electrode, and a gate electrode. The first insulating layer is disposed between the source electrode and the gate electrode and between the drain electrode and the gate electrode. The first insulating layer has a first portion and a second portion. The first portion is defined as a portion overlapped with the source electrode and the drain electrode. The second portion is defined as a portion not overlapped with the source electrode and the drain electrode. A thickness of the first portion is greater than a thickness of the second portion.

According to an embodiment of the disclosure, an electronic device includes a substrate, a circuit layer, and a light detection element. The circuit layer is disposed on the substrate and includes a transistor. The light detection element is disposed on the circuit layer and electrically connected to the transistor. The circuit layer includes a first insulating layer. The first insulating layer has different thicknesses.

### BRIEF DESCRIPTION OF THE DRAWINGS

The accompanying drawings are included to further understand the disclosure, and the drawings are incorporated in the specification and constitute a part of the specification. The drawings illustrate embodiments of the disclosure and, together with the description, serve to explain principles of the disclosure.

FIG. 1 is a schematic cross-sectional view of an electronic device of an embodiment of the disclosure.

FIG. 2 is a schematic cross-sectional view of an electronic device of another embodiment of the disclosure.

FIG. 3 is a schematic cross-sectional view of an electronic device of another embodiment of the disclosure.

FIG. 4 is a schematic cross-sectional view of an electronic device of another embodiment of the disclosure.

FIG. 5 is a schematic cross-sectional view of an electronic device of another embodiment of the disclosure.

FIG. 6A is a schematic top view of an electronic device of another embodiment of the disclosure.

FIG. 6B is a schematic cross-sectional view of the electronic device of FIG. 6A along section line I-I′.

### DESCRIPTION OF THE EMBODIMENTS

The disclosure may be understood by referring to the following detailed description in conjunction with the accompanying drawings. It should be noted that in order to facilitate understanding to the reader and to simplify the drawings, the multiple drawings in the disclosure depict a part of the electronic device, and certain elements in the drawings are not drawn to actual scale. In addition, the number and size of each element in the figures are for illustration, and are not intended to limit the scope of the disclosure.

In the following description and claims, the words “including” and “containing” and the like are open words, so they should be interpreted as meaning “including but not limited to . . . ”

It should be understood that when an element or film layer is referred to as “on” or “connected to” to another element or film layer, the element or film layer may be directly on the other element or film layer or directly connected to the other element or layer, or there is an inserted element or film layer between the two (indirect case). Conversely, when an element is referred to as “directly” on or “directly connected” to another element or film layer, there is no intervening element or film layer between the two.

Although the terms “first”, “second”, “third” . . . may be used to describe various constituent elements, the constituent elements are not limited to these terms. These terms are used to distinguish a single constituent element from other constituent elements in the specification. The same terms may not be used in the claims, and the elements in the claims may be replaced with first, second, third . . . according to the order declared by the elements in the claims. Therefore, in the following description, the first constituent element may be the second constituent element in the claims.

In the text, the terms “about”, “approximately”, “substantially”, “essentially” generally mean within 10%, or within 5%, or within 3%, or within 2%, or within 1%, or within 0.5% of a given value or range. Quantities given herein are approximate quantities, that is, in the absence of a specific description of “about”, “approximately”, “substantially”, “essentially”, the meanings of “about”, “approximately”, “substantially”, “essentially” may still be implied.

In some embodiments of the disclosure, terms such as “connection”, “interconnection”, etc. regarding bonding and connection, unless specifically defined, may mean that two structures are in direct contact, or that two structures are not in direct contact and there are other structures located between these two structures. Moreover, the terms of bonding and connecting may also include the case where both structures are movable or both structures are fixed. In addition, the term “coupled” includes any direct and indirect electrical connection means.

In some embodiments of the disclosure, optical microscopy (OM), scanning electron microscope (SEM), film thickness profile measuring instrument (α-step), ellipsometer, or other suitable methods may be used to measure the area, width, thickness, or height of each element, or the distance or spacing between elements. Specifically, according to some embodiments, a scanning electron microscope may be used to obtain a cross-sectional structure image including the element to be measured, and the area, width, thickness, or height of each element, or the distance or spacing between elements may be measured.

The electronic device of the disclosure may include a display device, an antenna device, a sensing device, or a tiling device, but the disclosure is not limited thereto. The electronic device may be a bendable or flexible electronic device. The electronic device may include, for example, a liquid-crystal light-emitting diode (LED); and the LED may include, for example, an organic light-emitting diode (OLED), mini LED, micro LED, or quantum dot (QD) LED (such as QLED), fluorescence, phosphor, or other suitable materials, and the materials thereof may be arranged and combined arbitrarily, but the disclosure is not limited thereto. The antenna device may be, for example, a liquid-crystal antenna, but the disclosure is not limited thereto. The tiling device may be, for example, a display tiling device or an antenna tiling device, but the disclosure is not limited thereto. It should be noted that the electronic device may be any combination of the above, but the disclosure is not limited thereto. Hereinafter, the disclosure will be described with an electronic device, but the disclosure is not limited thereto.

It should be noted that in the following embodiments, the features in several different embodiments may be replaced, recombined, and mixed to complete other embodiments without departing from the spirit of the disclosure. As long as the features between the embodiments do not violate the spirit of the disclosure or conflict with each other, they may be mixed and used arbitrarily.

Hereinafter, reference will be made in detail to exemplary embodiments of the disclosure, and examples of the exemplary embodiments are illustrated in the figures. Wherever possible, the same reference numerals are used in the figures and the descriptions to refer to the same or similar portions.

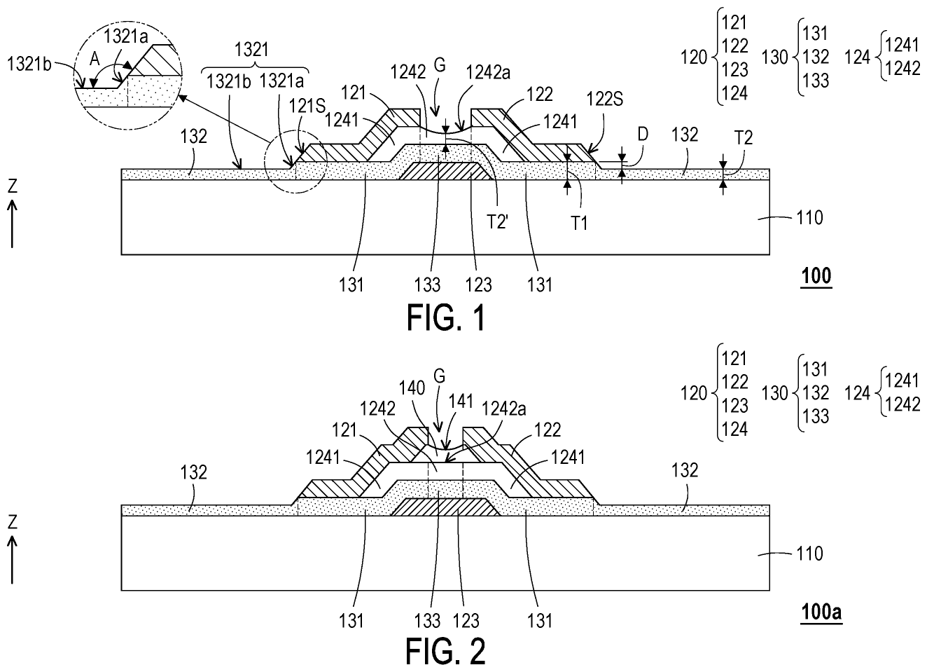

FIG. 1 is a schematic cross-sectional view of an electronic device of an embodiment of the disclosure. Referring to FIG. 1, an electronic device 100 of the present embodiment includes a substrate 110, a transistor 120, and a first insulating layer 130. In particular, the substrate 110 may include a rigid substrate, a flexible substrate, or a combination of the above. For example, the material of the substrate 110 may include glass, quartz, sapphire, ceramics, polycarbonate (PC), polyimide (PI), polyethylene terephthalate (PET), other suitable substrate materials, or a combination of the above, but the disclosure is not limited thereto.

In the present embodiment, the transistor 120 is disposed on the substrate 110. The transistor 120 may be, for example, an amorphous silicon thin-film transistor (TFT), a polysilicon such as a low-temperature polysilicon (LTPS) TFT, indium gallium zinc oxide (IGZO) TFT, other suitable transistors, or a combination of the above, but the disclosure is not limited thereto. Moreover, the type of the transistor 120 may be, for example, a switch TFT, a driving TFT, a scan TFT, a reset TFT, or other suitable transistors, but the disclosure is not limited thereto.

Specifically, the transistor 120 includes a source electrode 121, a drain electrode 122, a gate electrode 123, and a semiconductor layer 124. The gate electrode 123 is disposed on the substrate 110. The semiconductor layer 124 is disposed on the gate electrode 123, and the semiconductor layer 124 may be overlapped with the gate electrode 123 in a normal direction Z of the substrate 110. The source electrode 121 and the drain electrode 122 are disposed on the semiconductor layer 124, and the semiconductor layer 124 may be disposed between the source electrode 121 and the gate electrode 123 and between the drain electrode 122 and the gate electrode 123. In the present embodiment, the source electrode 121 and the drain electrode 122 may be in contact with a portion 1241 of the semiconductor layer 124 to be electrically connected to the semiconductor layer 124, there is a gap G between the source electrode 121 and the drain electrode 122, and the gap G may expose another portion 1242 of the semiconductor layer 124. The other portion 1242 may at least be overlapped with the gate electrode 123 in the normal direction Z of the substrate 110, and an upper surface 1242a of the other portion 1242 (i.e., the surface of the other portion 1242 facing away from the gate electrode 123) may have an arc edge, but the disclosure is not limited thereto.

In the present embodiment, the transistor 120 may be, for example, a top gate transistor, but the disclosure is not limited thereto, and in some embodiments, the transistor may also be a bottom gate transistor or a dual gate or double gate transistor. In the present embodiment, the material of the semiconductor layer 124 may include, but is not limited to, amorphous silicon, low-temperature polysilicon, metal oxide (e.g., indium gallium zinc oxide), other suitable materials, or a combination of the above, but the disclosure is not limited thereto.

In the present embodiment, the first insulating layer 130 is disposed on the gate electrode 123. The first insulating layer 130 may cover the substrate 110. The first insulating layer 130 is disposed between the source electrode 121 and the gate electrode 123 and between the drain electrode 122 and the gate electrode 123. In the present embodiment, the first insulating layer 130 may be in contact with the semiconductor layer 124, and the first insulating layer 130 may be in contact with the gate electrode 123 and/or the substrate 110, but the disclosure is not limited thereto. In the present embodiment, the first insulating layer 130 may have a single-layer or multi-layer structure, and the material of the first insulating layer 130 may include an organic material, inorganic material, or a combination of the above, but the disclosure is not limited thereto.

Specifically, the first insulating layer 130 has a first portion 131, a second portion 132, and a second portion 133. The first portion 131 may be defined as the portion of the first insulating layer 130 overlapped with the source electrode 121 and the drain electrode 122 in the normal direction Z of the substrate 110, and the second portion 132 and the second portion 133 may be defined as the portion of the first insulating layer 130 not overlapped with the source electrode 121 and the drain electrode 122 in the normal direction Z of the substrate 110. In particular, the second portion 132 may be not overlapped with the gate electrode 123 in the normal direction Z of the substrate 110, for example, and the second portion 133 may be overlapped with the gate electrode 123 in the normal direction Z of the substrate 110, for example. In some embodiments, the first portion 131 may, for example, be completely overlapped with the source electrode 121 and the drain electrode 122 in the normal direction Z of the substrate 110.

In the present embodiment, the first portion 131 has a thickness T1, the second portion 132 has a thickness T2, and the second portion 133 has a thickness T2′. The thickness T1 of the first portion 131 is greater than the thickness T2 of the second portion 132. The thickness T1 of the first portion 131 is, for example, equal to the thickness T2′ of the second portion 133. In particular, the thickness T1 of the first portion 131 is, for example, the minimum thickness of the first portion 131 measured along the normal direction Z of the substrate 110 in a cross section, the thickness T2 of the second portion 132 is, for example, the minimum thickness of the second portion 132 measured along the normal direction Z of the substrate 110, and the thickness T2′ of the second portion 133 is, for example, the minimum thickness of the second portion 133 measured along the normal direction Z of the substrate 110. In some embodiments, a difference D between the thickness T1 of the first portion 131 and the thickness T2 of the second portion 132 may be greater than or equal to 0.01 micrometers (μm) and less than the thickness T1 of the first portion 131 (i.e., 0.01 μm≤difference<T1), but the disclosure is not limited thereto. In some embodiments, the second portion 132 may be regarded as a recess of the first insulating layer 130, and the depth of the recess may be substantially equal to the difference D, but the disclosure is not limited thereto.

In the present embodiment, in a cross-section, an upper surface 1321 of the second portion 132 has an oblique edge 1321a and a horizontal edge 1321b connected to each other. There may be an angle A between the oblique edge 1321a and the horizontal edge 1321b, and the angle A may be greater than or equal to 90° (degrees) and less than 180° (i.e., 90°≤SA<180°), but the disclosure is not limited thereto. In some embodiments, the angle A may also be greater than or equal to 95 degrees and less than or equal to 175 degrees, greater than or equal to 100 degrees and less than or equal to 170 degrees, or greater than or equal to 105 degrees and less than or equal to 165 degrees. In some embodiments, the oblique edge 1321a of the second portion 132 and a side edge 121S of the source electrode 121 or a side edge 122S of the drain electrode 122 may be aligned or not aligned. When the oblique edge 1321a of the second portion 132 is aligned with the side edge 121S of the source electrode 121 or the side edge 122S of the drain electrode 122, the oblique edge 1321a and the side edge 121S or the side edge 122S may be connected to each other, for example. When the oblique edge 1321a of the second portion 132 is not aligned with the side edge 121S of the source electrode 121 or the side edge 122S of the drain electrode 122, the oblique edge 1321a and the side edge 121S or the side edge 122S may be not connected to each other, for example.

In the present embodiment, the method of thinning the second portion 132 of the first insulating layer 130 may include, but is not limited to, the following steps: first, the first insulating layer 130 is formed on the gate electrode 123 so that the first insulating layer 130 may cover the gate electrode 123 and the substrate 110; then, the semiconductor layer 124 is formed on the first insulating layer 130, so that the semiconductor layer 124 may be overlapped with the gate electrode 123 in the normal direction Z of the substrate 110; next, an electrode material layer (not shown) is formed on the semiconductor layer 124, so that the electrode material layer may cover the semiconductor layer 124 and the first insulating layer 130; next, an etching process is performed on the electrode material layer to form the source electrode 121 and the drain electrode 122, wherein the source electrode 121 and the drain electrode 122 are in contact with the portion 1241 of the semiconductor layer 124 and expose the other portion 1242 of the semiconductor layer 124; then, the etching process further over-etches the second portion 132 of the first insulating layer 130 and the other portion 1242 of the semiconductor layer 124 exposed by the source electrode 121 and the drain electrode 122, so that the thickness T2 of the second portion 132 may be less than the thickness T1 of the first portion 131. In a cross-section, the upper surface 1242a of the other portion 1242 may have an arc edge.

In some embodiments, the method of thinning the second portion 132 of the first insulating layer 130 may include, but is not limited to, the following steps: first, the first insulating layer 130 is formed on the gate electrode 123 so that the first insulating layer 130 may cover the gate electrode 123 and the substrate 110; then, the semiconductor layer 124 is formed on the first insulating layer 130, so that the semiconductor layer 124 may be overlapped with the gate electrode 123 in the normal direction Z of the substrate 110; next, an electrode material layer (not shown) is formed on the semiconductor layer 124, so that the electrode material layer may cover the semiconductor layer 124 and the first insulating layer 130; next, an etching process is performed on the electrode material layer to form the source electrode 121 and the drain electrode 122 on the semiconductor layer 124; then, an etching process is performed on the second portion 132 of the first insulating layer 130 and/or the other portion 1242 of the semiconductor layer 124 exposed by the source electrode 121 and the drain electrode 122, so that the thickness T2 of the second portion 132 may be less than the thickness T1 of the first portion 131, and the upper surface 1242a of the other portion 1242 may have an arc edge. In some embodiments, the middle portion of the other portion 1242 has, for example, a recess, so that the upper surface 1242a of the other portion 1242 has an arc edge. In some embodiments, the upper surface 1242a of the other portion 1242 may include other irregular shapes.

In the present embodiment, by reducing the thickness T2 of the second portion 132 of the first insulating layer 130 to make the thickness T2 of the second portion 132 less than the thickness T1 of the first portion 131, the hydrogen content in the first insulating layer 130 may be reduced to reduce the issue of characteristic shift of the transistor 120 or improve the performance of the transistor 120.

Other embodiments are listed below for description. It must be noted here that the following embodiments adopt the reference numerals and part of the content of the above embodiments, wherein the same reference numerals are used to represent the same or similar elements, and the description of the same technical content is omitted. For the description of the omitted parts, reference may be made to the above embodiments, which is not repeated in the following embodiments.

FIG. 2 is a schematic cross-sectional view of an electronic device of another embodiment of the disclosure. Please refer to FIG. 1 and FIG. 2 at the same time. An electronic device 100a of the present embodiment is similar to the electronic device 100 in FIG. 1, but the differences between the two are: the electronic device 100a of the present embodiment further includes a second insulating layer 140.

Specifically, referring to FIG. 2, in the present embodiment, the second insulating layer 140 is disposed on the semiconductor layer 124 and overlapped with the other portion 1242 of the semiconductor layer 124. The second insulating layer 140 is disposed between the source electrode 121, the drain electrode 122, and the semiconductor layer 124. In particular, the second insulating layer 140 may have a single-layer or multi-layer structure, and the material of the second insulating layer 140 may include an organic material, inorganic material, or a combination of the above, but the disclosure is not limited thereto.

In the present embodiment, since the second insulating layer 140 may cover the other portion 1242 of the semiconductor layer 124, the upper surface 1242a of the other portion 1242 may not have an arc edge, for example. Moreover, since the second insulating layer 140 may be exposed by the gap G between the source electrode 121 and the drain electrode 122, the upper surface 141 of the second insulating layer 140 (i.e., the surface of the second insulating layer 140 facing away from the semiconductor layer 124) may have an arc edge. In some embodiments, the middle portion of the second insulating layer 140 has, for example, a recess, so that the upper surface 141 of the second insulating layer 140 has an arc edge. In some embodiments, the upper surface 141 of the second insulating layer 140 may include other irregular shapes.

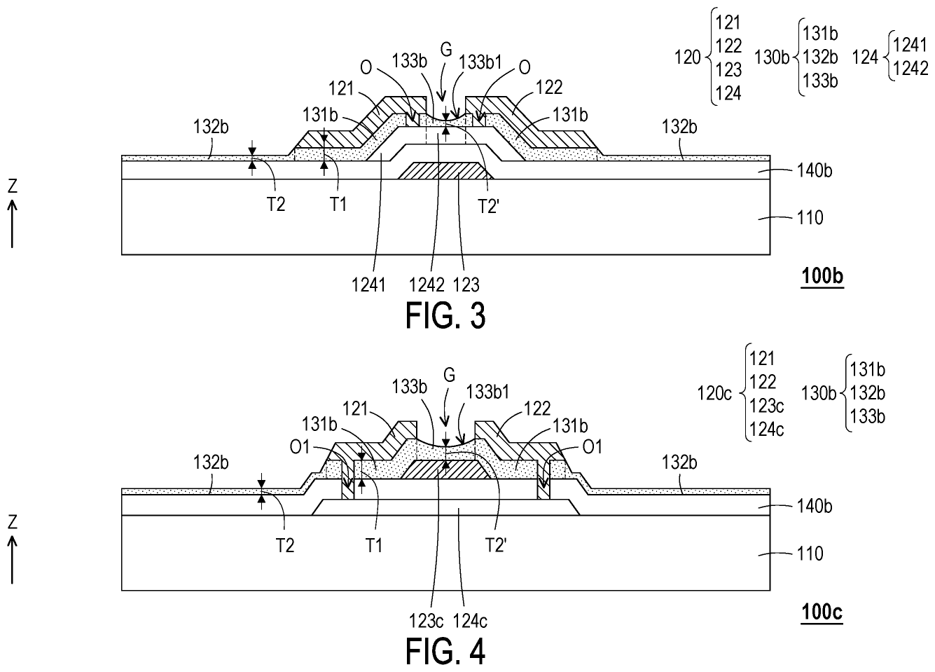

FIG. 3 is a schematic cross-sectional view of an electronic device of another embodiment of the disclosure. Please refer to FIG. 1 and FIG. 3 at the same time. An electronic device 100b of the present embodiment is similar to the electronic device 100 in FIG. 1, but the differences between the two are: in the electronic device 100b of the present embodiment, a first insulating layer 130b may be disposed on the semiconductor layer 124, and the electronic device 100b further includes a second insulating layer 140b.

Specifically, referring to FIG. 3, in the present embodiment, the second insulating layer 140b is disposed on the substrate 110 and between the semiconductor layer 124 and the gate electrode 123. The second insulating layer 140b may be in contact with the semiconductor layer 124, the gate electrode 123, and the substrate 110, but the disclosure is not limited thereto. The semiconductor layer 124 may be disposed on the second insulating layer 140b.

The first insulating layer 130b may be disposed on the semiconductor layer 124 to cover the semiconductor layer 124 and the second insulating layer 140b. The first insulating layer 130b may be disposed between the source electrode 121, the drain electrode 122, and the semiconductor layer 124. The first insulating layer 130b may be disposed between the source electrode 121, the drain electrode 122, and the drain electrode 123. The first insulating layer 130b may be in contact with the semiconductor layer 124 and not in contact with the gate electrode 123 and the substrate 110. The thickness T1 of a first portion 131b of the first insulating layer 130b may be greater than the thickness T2 of a second portion 132b or the thickness T2′ of a second portion 133b. The definitions of the thickness T1, the thickness T2, and the thickness T2′ are as provided above.

In the present embodiment, since the first insulating layer 130b may cover the other portion 1242 of the semiconductor layer 124, the upper surface 1242a of the other portion 1242 does not have an arc edge. Moreover, since the second portion 133b of the first insulating layer 130b (that is, the portion of the second portion 133b overlapped with the gate electrode 123 in the normal direction Z of the substrate 110) may be exposed by the gap G between the source electrode 121 and the drain electrode 122, the upper surface 133b1 of the second portion 133b (i.e., the surface of the second portion 133b facing away from the semiconductor layer 124) may have an arc edge. In other words, in a cross-section, the upper surface 133b1 of the portion of the second portion 133b overlapped with the gate electrode 123 has an arc edge. In some embodiments, the source electrode 121 and the drain electrode 122 are electrically connected to the semiconductor layer 124 via, for example, an opening O of the first insulating layer 130b. In some embodiments, the thickness T2 of the second portion 132b may be, for example, less than or equal to the thickness T2′ of the second portion 133b. In some embodiments, the opening O of the first insulating layer 130b may be overlapped with the gate electrode 123, but the disclosure is not limited thereto. In some embodiments, the cross-sectional structure of the second portion 132b of the first insulating layer 130b is, for example, stepped, but the disclosure is not limited thereto.

In the present embodiment, by reducing the thickness T2 of the second portion 132b of the first insulating layer 130b to make the thickness T2 of the second portion 132b or the thickness T2′ of the second portion 133b less than the thickness T1 of the first portion 131b, the hydrogen content in the first insulating layer 130b may be reduced to reduce the issue of characteristic shift of the transistor 120 or improve the performance of the transistor 120.

In some embodiments not shown, the portion of the second insulating layer 140b not overlapped with the source electrode 121 and the drain electrode 122 in the normal direction Z of the substrate 110 may be selectively thinned to reduce the hydrogen content in the second insulating layer 140b, in order to further reduce the issue of characteristic shift of the transistor 120 or further improve the performance of the transistor 120.

FIG. 4 is a schematic cross-sectional view of an electronic device of another embodiment of the disclosure. Please refer to FIG. 3 and FIG. 4 at the same time. An electronic device 100c of the present embodiment is similar to the electronic device 100b in FIG. 3, but the differences between the two are: in the electronic device 100c of the present embodiment, the transistor 120c is a top-gate transistor.

Specifically, referring to FIG. 4, a semiconductor layer 124c is disposed between the second insulating layer 140b and the substrate 110, and a gate electrode 123c is disposed between the first insulating layer 130b and the second insulating layer 140b. The second insulating layer 140b is disposed between the semiconductor layer 124c and the gate electrode 123c. The gate electrode 123c is disposed on the semiconductor layer 124c, the first insulating layer 130b is disposed on the gate electrode 123c, and the first insulating layer 130b is not in contact with the semiconductor layer 124c. In the present embodiment, the width of the semiconductor layer 124c may be greater than the width of the gate electrode 123c in a cross section, but the disclosure is not limited thereto.

In the present embodiment, for example, the source electrode 121 and the drain electrode 122 are separated from the semiconductor layer 124c by the first insulating layer 130b and the second insulating layer 140b, and the source electrode 121 and the drain electrode 122 are electrically connected to the semiconductor layer 124c via, for example, an opening O1 of the first insulating layer 130b and the second insulating layer 140b, respectively. In some embodiments, the thickness T2 of the second portion 132b of the first insulating layer 130b or the thickness T2′ of the second portion 133b may be, for example, less than or equal to the thickness T1 of the first portion 131b of the first insulating layer 130b. In some embodiments, the thickness T2 of the second portion 132b of the first insulating layer 130b may be, for example, less than or equal to the thickness T2′ of the second portion 133b of the first insulating layer 130b. In the present embodiment, the cross-sectional structure of the second portion 132b of the first insulating layer 130b is, for example, stepped, but the disclosure is not limited thereto.

In some embodiments not shown, the portion of the second insulating layer 140b not overlapped with the source electrode 121 and the drain electrode 122 in the normal direction Z of the substrate 110 may be further thinned to reduce the hydrogen content in the second insulating layer 140b, in order to further reduce the issue of characteristic shift of the transistor 120 or further improve the performance of the transistor 120.

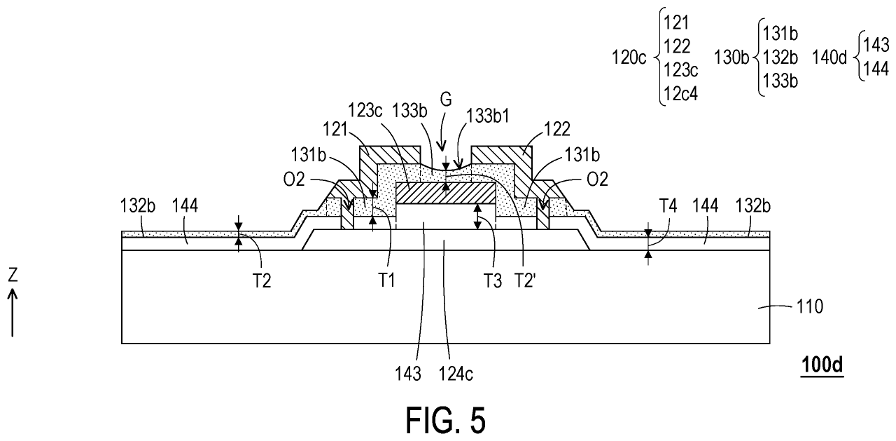

FIG. 5 is a schematic cross-sectional view of an electronic device of another embodiment of the disclosure. Please refer to FIG. 4 and FIG. 5 at the same time. An electronic device 100d of the present embodiment is similar to the electronic device 100c in FIG. 4, but the differences between the two are: in the electronic device 100d of the present embodiment, the thickness of a portion of a second insulating layer 140d may be reduced.

Specifically, referring to FIG. 5, in the present embodiment, the second insulating layer 140d may be disposed between the semiconductor layer 124c and the gate electrode 123c. The second insulating layer 140d has a third portion 143 and a fourth portion 144. In particular, the third portion 143 may be defined as a portion of the second insulating layer 140d overlapped with the gate electrode 123c in the normal direction Z of the substrate 110, and the fourth portion 144 may be defined as a portion of the second insulating layer 140d not overlapped with the gate electrode 123c in the normal direction Z of the substrate 110. In some embodiments, the third portion 143 may, for example, be completely overlapped with the gate electrode 123c in the normal direction Z of the substrate 110.

In the present embodiment, the third portion 143 has a thickness T3, the fourth portion 144 has a thickness T4, and the thickness T3 of the third portion 143 is greater than the thickness T4 of the fourth portion 144. In particular, the thickness T3 of the third portion 143 is, for example, the minimum thickness of the third portion 143 along the normal direction Z of the substrate 110 under a cross-sectional structure, and the thickness T4 of the fourth portion 144 is, for example, the minimum thickness of the fourth portion 144 along the normal direction Z of the substrate 110 under a cross-sectional structure. In the present embodiment, the source electrode 121 and the drain electrode 122 are electrically connected to the semiconductor layer 124c via, for example, an opening O2 of the first insulating layer 130b (e.g., the first portion 131b) and the second insulating layer 140d (e.g., the fourth portion 144). In the present embodiment, the thickness T2 of the second portion 132b may be, for example, less than or equal to the thickness T1 of the first portion 131b, and the thickness T2 of the second portion 132b may be, for example, less than or equal to the thickness T2′ of the second portion 133b. In the present embodiment, the cross-sectional structure of the second portion 132b of the first insulating layer 130b is, for example, stepped, but the disclosure is not limited thereto.

In the present embodiment, by reducing the thickness T4 of the fourth portion 144 of the second insulating layer 140d to make the thickness T4 of the fourth portion 144 less than the thickness T3 of the third portion 143, the hydrogen content in the second insulating layer 140d may be reduced to further reduce the issue of characteristic shift of the transistor 120d or further improve the performance of the transistor 120c.

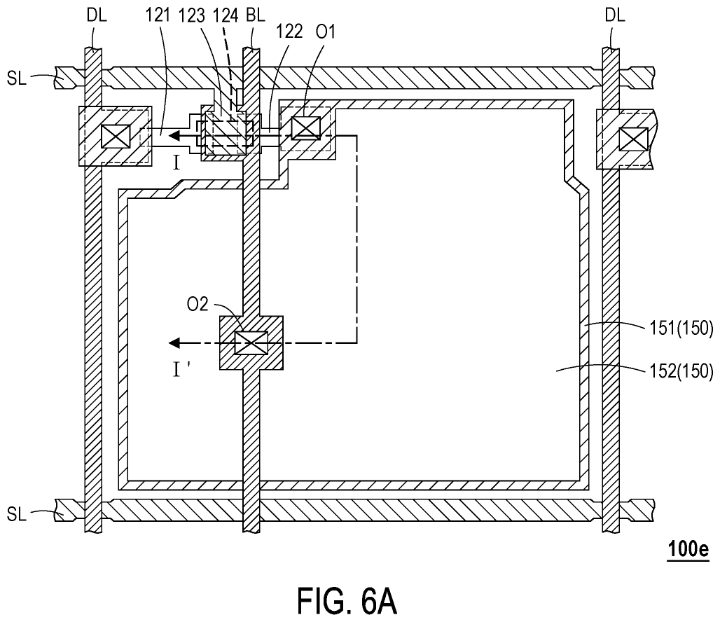

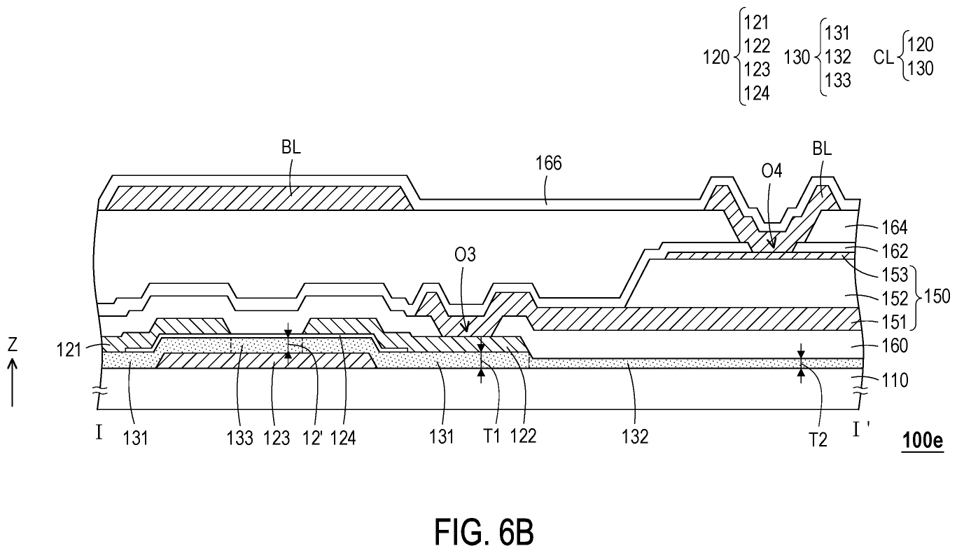

FIG. 6A is a schematic top view of an electronic device of another embodiment of the disclosure. FIG. 6B is a schematic cross-sectional view of the electronic device of FIG. 6A along section line I-I′. For the clarity of the drawings and the convenience of description, FIG. 6A omits to show some elements in an electronic device 100e.

Referring to FIG. 6A and FIG. 6B, the electronic device 100e of the present embodiment includes the substrate 110, a circuit layer CL, and a light detection element 150. The circuit layer CL is disposed on the substrate 110. The circuit layer CL is disposed on the substrate 110 and includes the transistor 120 as shown in FIG. 1 and the first insulating layer 130 as shown in FIG. 1, and therefore details are not repeated herein. The circuit layer CL may be defined as all laminations between the uppermost conductive layer of the transistor 120 (i.e., the uppermost layer in the source electrode 121, the drain electrode 122, or the gate electrode 123, but the disclosure is not limited thereto) and the surface of the substrate 110.

In the present embodiment, the circuit layer CL includes the first insulating layer 130. The first insulating layer 130 may have the first portion 131, the second portion 132, and the second portion 133. The first portion 131 may be defined as the portion of the first insulating layer 130 overlapped with the source electrode 121 and the drain electrode 122 in the normal direction Z of the substrate 110, and the second portion 132 and the second portion 133 may be defined as the portion of the first insulating layer 130 not overlapped with the source electrode 121 and the drain electrode 122 in the normal direction Z of the substrate 110. In particular, the second portion 132 may not be overlapped with the gate electrode 123 in the normal direction Z of the substrate 110, and the second portion 133 may be overlapped with the gate electrode 123 in the normal direction Z of the substrate 110. In some embodiments, the first portion 131 may, for example, be completely overlapped with the source electrode 121 and the drain electrode 122 in the normal direction Z of the substrate 110, but the disclosure is not limited thereto. The second portion 133 may be completely overlapped with the gate electrode 123 in the normal direction Z of the substrate 110.

The first insulating layer 130 may have different thicknesses. Specifically, the first portion 131 of the first insulating layer 130 has the thickness T1, the second portion 132 of the first insulating layer 130 has the thickness T2, and the second portion 133 thereof has the thickness T2′. The thickness T1 of the first portion 131 is greater than the thickness T2 of the second portion 132. The definitions of the thickness T1, the thickness T2, or the thickness T2′ are as previously described. In the present embodiment, since the first insulating layer 130 may have different thicknesses, the hydrogen content in the first insulating layer 130 may be reduced, so as to reduce the issue of characteristic shift of the transistor 120 or improve the performance of the transistor 120.

In the present embodiment, the electronic device 100e further includes a scan line SL, a data line DL, an insulating layer 160, an insulating layer 162, a planarization layer 164, a bias signal line BL, and/or a protective layer 166. Specifically, as shown in FIG. 6A, the scan line SL may be intersected with the data line DL, and the scan line SL may be intersected with the bias signal line BL, but the disclosure is not limited thereto. In some embodiments, the extending directions of the data line DL and the bias signal line BL may be substantially the same. In some embodiments, the data line DL and the bias signal line BL are not overlapped, for example, in the normal direction Z of the substrate 110. The scan line SL may be electrically connected to the transistor 120 via the gate electrode 123, and the data line DL may be electrically connected to the transistor 120 via the source electrode 121.

Please continue to refer to FIG. 6B, the insulating layer 160 may be disposed on the transistor 120 to cover the source electrode 121, the semiconductor layer 124, the drain electrode 122, and the second portion 132 of the first insulating layer 130. The insulating layer 160 may have a single-layer or multi-layer structure, and the material of the insulating layer 160 may include an organic material, inorganic material, or a combination of the above, but the disclosure is not limited thereto.

The light detection element 150 is disposed on the circuit layer CL and electrically connected to the transistor. Specifically, the light detection element 150 may include a lower electrode 151, an active layer 152, and an upper electrode 153. The lower electrode 151 may be disposed on the insulating layer 160, and the lower electrode 151 may be electrically connected to the drain electrode 122 via an opening O3 of the insulating layer 160, but the disclosure is not limited thereto. The active layer 152 may be disposed on the lower electrode 151 and located between the lower electrode 151 and the upper electrode 153. The active layer 152 may be, for example, a stacked structure (e.g., a PIN photodiode) formed by a P-type semiconductor, an intrinsic semiconductor, and an N-type semiconductor, but the disclosure is not limited thereto.

In the normal direction Z of the substrate 110, the area of the lower electrode 151 may be greater than or equal to the area of the active layer 152. In the normal direction Z of the substrate 110, the area of the active layer 152 may be greater than or equal to the area of the upper electrode 153. In some embodiments, the thickness of the lower electrode 151 may be different from the thickness of the upper electrode 153. In some embodiments, the material of the lower electrode 151 may be different from the material of the upper electrode 153. In some embodiments, the lower electrode 151 may be a metal material, and the upper electrode 153 may be a transparent conductive material, but the disclosure is not limited thereto. In the normal direction Z of the substrate 110, the lower electrode 151 may be not overlapped with the scan line SL and/or the data line DL, for example. In some embodiments, in the normal direction Z of the substrate 110, the bias signal line BL is overlapped with the transistor 120 and/or the scan line SL, for example. In some embodiments, in the normal direction Z of the substrate 110, the bias signal line BL is not overlapped with the data line DL, for example.

In some embodiments, the insulating layer 162 is disposed on the light detection element 150 to cover the light detection element 150 and the transistor 120. The planarization layer 164 may be disposed on the insulating layer 162. The bias signal line BL may be disposed on the planarization layer 164, and the bias signal line BL may be electrically connected to the upper electrode 153 of the light detection element 150 via an opening O4 penetrating the planarization layer 164 and the insulating layer 162. The protective layer 166 may be disposed on the bias signal line BL to cover the bias signal line BL and the planarization layer 164. In the present embodiment, the insulating layer 162, the planarization layer 164, and the protective layer 166 may be single-layer or multi-layer structures, and the material of the insulating layer 162, the planarization layer 164, and the protective layer 166 may include an organic material, an inorganic material, or a combination of the above, but the disclosure is not limited thereto.

Although the present embodiment applies the transistor 120 shown in FIG. 1 and the first insulating layer 130 shown in FIG. 1 in the electronic device 100e including the light detection element 150 (e.g., a PIN photodiode), the disclosure is not limited thereto. In some embodiments, the transistor 120 shown in FIG. 1 and the first insulating layer 130 shown in FIG. 1 may also be applied to an electronic device (not shown) including a pixel unit. In some embodiments, the transistor and the first insulating layer shown in FIG. 2, FIG. 3, FIG. 4, or FIG. 5 may also be applied to an electronic device including a light detection element (or pixel unit).

Based on the above, in the electronic device of an embodiment of the disclosure, by reducing the thickness of the second portion of the first insulating layer to make the thickness of the second portion less than the thickness of the first portion, the hydrogen content in the first insulating layer may be reduced to reduce the issue of characteristic shift of the transistor or improve the performance of the transistor. Moreover, by further reducing the thickness of the fourth portion of the second insulating layer to make the thickness of the fourth portion less than the thickness of the third portion, the hydrogen content in the second insulating layer may also be reduced to further reduce the issue of characteristic shift of the transistor or further improve the performance of the transistor.

Although the disclosure is disclosed as above by the embodiments, the embodiments are not intended to limit the disclosure. Any person of ordinary skill in the art may make some changes and modifications without departing from the spirit and scope of the disclosure. Therefore, the scope of the disclosure shall be subject to what is defined in the appending claims.

What is claimed is:

1. An electronic device, comprising:
a substrate;
a transistor disposed on the substrate and comprising a source electrode, a drain electrode, and a gate electrode; and
a first insulating layer disposed between the source electrode and the gate electrode and between the drain electrode and the gate electrode,
wherein the first insulating layer has a first portion and a second portion, the first portion is defined as a portion overlapped with the source electrode and the drain electrode, the second portion is defined as a portion not overlapped with the source electrode and the drain electrode, and a thickness of the first portion is greater than a thickness of the second portion.

2. The electronic device of claim 1, wherein a difference between the thickness of the first portion and the thickness of the second portion is greater than or equal to 0.01 micrometers and less than the thickness of the first portion.

3. The electronic device of claim 1, wherein the transistor comprises a semiconductor layer, and the first insulating layer is in contact with the semiconductor layer.

4. The electronic device of claim 3, wherein the semiconductor layer is disposed between the source electrode and the gate electrode and between the drain electrode and the gate electrode.

5. The electronic device of claim 3, wherein the semiconductor layer is disposed between the gate electrode and the substrate.

6. The electronic device of claim 3, further comprising:
a second insulating layer disposed between the semiconductor layer and the source electrode and between the semiconductor layer and the drain electrode,
wherein an upper surface of the second insulating layer has an arc edge.

7. The electronic device of claim 3, further comprising:
a second insulating layer disposed between the semiconductor layer and the gate electrode.

8. The electronic device of claim 1, wherein the transistor comprises a semiconductor layer, and the first insulating layer is not in contact with the semiconductor layer.

9. The electronic device of claim 8, wherein the semiconductor layer is disposed between the gate electrode and the substrate.

10. The electronic device of claim 1, wherein in a cross section, an upper surface of a portion in the second portion overlapped with the gate electrode has an arc edge.

11. The electronic device of claim 1, wherein the transistor comprises a semiconductor layer, and the electronic device further comprises:
a second insulating layer disposed between the semiconductor layer and the gate electrode,
wherein the second insulating layer has a third portion and a fourth portion, the third portion is defined as a portion overlapped with the gate electrode, the fourth portion is defined as a portion not overlapped with the gate electrode, and a thickness of the third portion is greater than a thickness of the fourth portion.

12. The electronic device of claim 1, wherein in a cross-section, an upper surface of the second portion has an oblique edge and a horizontal edge connected to each other, there is an angle between the oblique edge and the horizontal edge, and the angle is greater than 90 degrees and less than 180 degrees.

13. The electronic device of claim 12, wherein the oblique edge of the second portion is aligned with a side edge of the source electrode or a side edge of the drain electrode.

14. The electronic device of claim 1, wherein the transistor comprises a semiconductor layer, the source electrode and the drain electrode are in contact with a portion of the semiconductor layer and expose another portion of the semiconductor layer, and in a cross section, an upper surface of the other portion has an arc edge.

15. The electronic device of claim 2, wherein the second portion is a recess of the first insulating layer, and a depth of the recess is substantially equal to the difference.

16. The electronic device of claim 1, wherein the first insulating layer has an opening, and the source electrode or the drain electrode is electrically connected to the semiconductor layer via the opening.

17. The electronic device of claim 1, wherein the opening is overlapped with the gate electrode.

18. An electronic device, comprising:
a substrate;
a circuit layer disposed on the substrate and comprising a transistor; and
a light detection element disposed on the circuit layer and electrically connected to the transistor,
wherein the circuit layer comprises a first insulating layer, and the first insulating layer has different thicknesses.

19. The electronic device of claim 18, wherein the transistor comprises a source electrode, a drain electrode, and a gate electrode, the first insulating layer is disposed between the source electrode and the gate electrode and between the drain electrode and the gate electrode, the first insulating layer has a first portion and a second portion, the first portion is defined as a portion overlapped with the source electrode and the drain electrode, the second portion is defined as a portion not overlapped with the source electrode and the drain electrode, and a thickness of the first portion is greater than a thickness of the second portion.

20. The electronic device of claim 18, wherein the light detection element comprises a lower electrode, an active layer, and an upper electrode, the active layer is disposed between the lower electrode and the upper electrode, and the light detection element is electrically connected to a drain electrode of the transistor via the lower electrode.
